(19) United States
(12) Patent Application Publication
(10) Pub. No.: US 2015/0289415 A1
(43) Pub. Date: Oct. 8, 2015

(54) COOLING FIN AND HEAT DISSIPATION MODULE HAVING THE SAME

(71) Applicant: ASUSTeK COMPUTER INC., Taipei City (TW)

(72) Inventors: Chun-Chieh Wong, Taipei City (TW); Cheng-Yu Wang, Taipei City (TW); Ing-Jer Chiou, Taipei City (TW)

(21) Appl. No.: 14/675,772

(22) Filed: Apr. 1, 2015

(30) Foreign Application Priority Data
Apr. 2, 2014 (CN) 201410131902.9

(51) Int. Cl. H05K 7/20

(52) U.S. Cl. CPC H05K 7/20409

(57) ABSTRACT

A cooling fin, applied in a heat dissipation module, includes a fin body, a penetration portion, and at least one bending portion. The penetration portion is formed on the fin body and includes a slot, a first bending wall, and a second bending wall. The first bending wall and the second bending wall are formed at the opposite sides of the slot. The bending portion is formed on the fin body and adjacent to one end of the slot.

### CROSS-REFERENCE TO RELATED APPLICATION

This application claims the priority benefit of Chinese application serial No. 201410131902.9, filed on Apr. 2, 2014. The entirety of the above-mentioned patent application is hereby incorporated by reference herein and made a part of specification.

### BACKGROUND OF THE INVENTION

1. Field of the Invention

The disclosure relates to a cooling fin and a heat dissipation module and, more particularly, to a cooling fin and a heat dissipation module for an electronic device.

2. Description of the Related Art

With the improvement of the efficiency of the thin central processing unit (CPU) and other electronic components in electronic products, active heat dissipation modules need to be used to avoid overheat. Specifically, in a thin electronic product, a heat pipe connecting with a cooling fin set is generally used for dissipating heat from heating elements, and a fan is further used to generate an airflow passing through the cooling fin set to dissipate heat.

In order to allocate the heat pipe to the cooling fin set and provide enough contacting area between the heat pipe and each cooling fin, each of cooling fins is usually punched to form a slot for the heat pipe to pass through the slot and contact with bending walls at two sides. As a result, the cooling fin must have enough space. However, the large size cooling fins are not suitable for thin-type electronic products.

### BRIEF SUMMARY OF THE INVENTION

A cooling fin, applied in a heat dissipation module, includes a fin body, a penetration portion, and at least one bending portion. The penetration portion is formed on the fin body and includes a slot, a first bending wall, and a second bending wall. The first bending wall and the second bending wall are formed at the opposite sides of the slot. The bending portion is formed at the fin body and adjacent to one end of the slot.

A heat dissipation module includes a cooling fin set and a heat pipe. The cooling fin set includes a plurality of cooling fins connected with each other. The cooling fin includes a fin body, a penetration portion, and at least one bending portion. The penetration portion is formed on the fin body and includes a slot, a first bending wall, and a second bending wall. The first bending wall and the second bending wall are formed at the opposite sides of the slot. The bending portion is formed at the fin body and adjacent to one end of the slot. The heat pipe passes each penetration portion via each slot and contacting the first bending wall and the second bending wall of the penetration portion.

In sum, the cooling fin of the cooling fin set includes the penetration portion for the heat pipe to pass through, and it also includes the bending portion adjacent to the penetration portion to decrease the height of the cooling fin and decrease the distance between the first bending wall and the second bending wall, which makes the heat dissipation module have small size to assemble with a thin heat pipe between the first bending wall and the second bending wall, meanwhile, it also has a better heat dissipation effect.

These and other features, aspects and advantages of the present disclosure will become better understood with regard to the following description, appended claims, and accompanying drawings.

### BRIEF DESCRIPTION OF THE DRAWINGS

FIG. 1 is a side view of a heat dissipation module in an embodiment;

FIG. 2 is a schematic diagram showing a cooling fin set and a heat pipe in FIG. 1;

FIG. 3 is a schematic diagram showing a cooling fin in FIG. 1;

FIG. 4 is a section diagram showing the cooling fin set and the heat pipe in FIG. 2 along line I-I;

FIG. 5 is a partial section diagram showing a cooling fin in another embodiment;

FIG. 6 is a schematic diagram showing a cooling fin in another embodiment; and

FIG. 7 is a schematic diagram showing a cooling fin in further another embodiment.

### DETAILED DESCRIPTION OF THE EMBODIMENTS

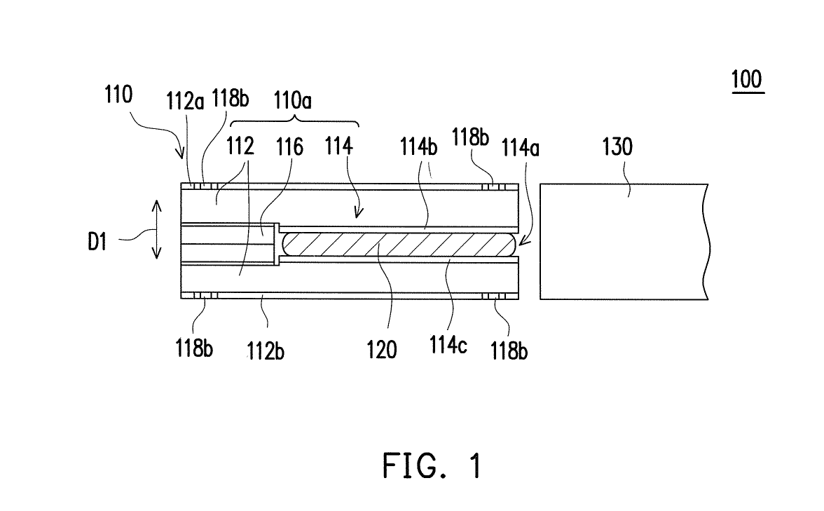

FIG. 1 is a side view of a heat dissipation module in an embodiment and the heat pipe 120 is shown from a section. Please refer to FIG. 1, the heat dissipation module 100 (which may be used at a thin electronic product such as a tablet PC or a smart phone) in the embodiment includes a cooling fin set 110 and a heat pipe 120. The heat pipe 120 is connected with the cooling fin set 110 and the heating element (not shown, such as a central processing unit) of the electronic product, and it transfers the heat generated by the heating element to the cooling fin set 110. The heat dissipation module may further include a fan 130 to provide an airflow to the cooling fin set 110 for heat dissipation.

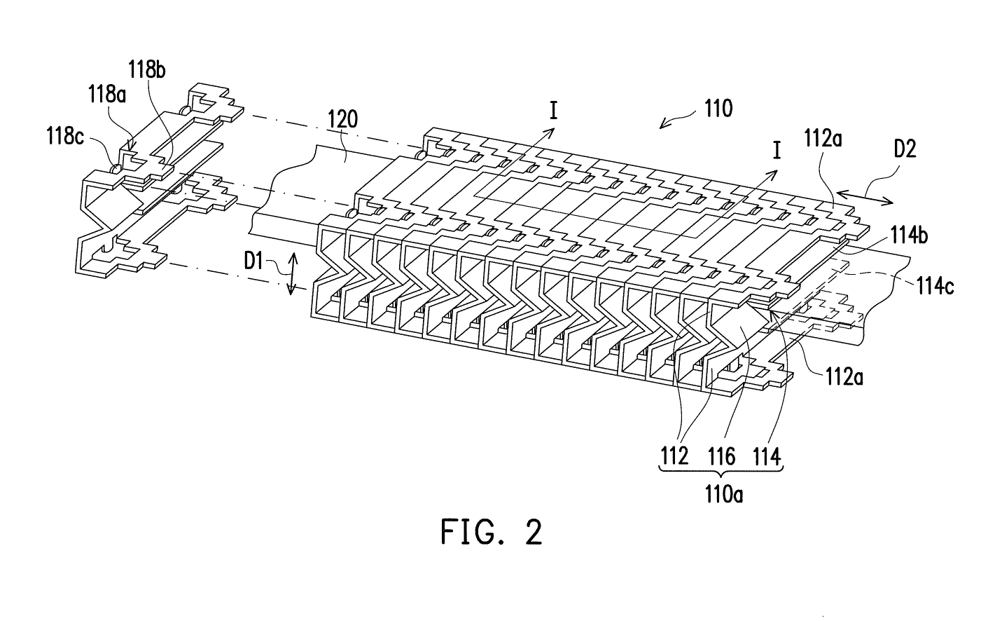

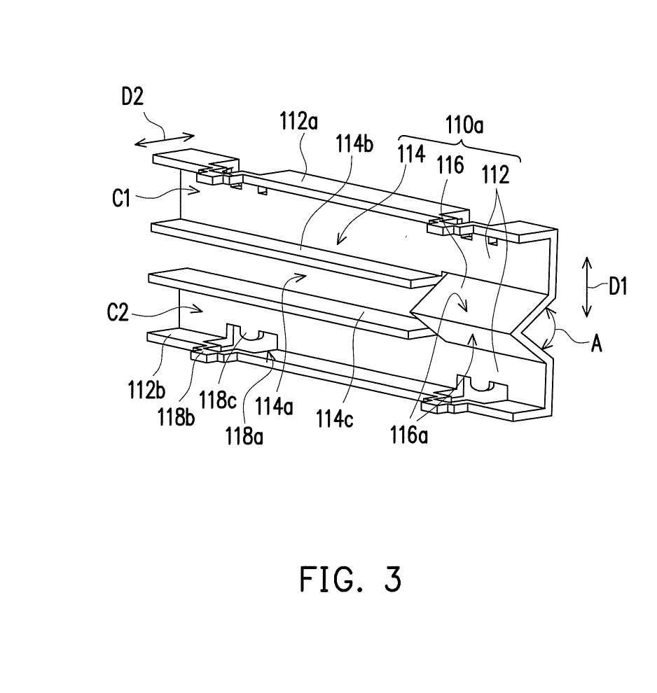

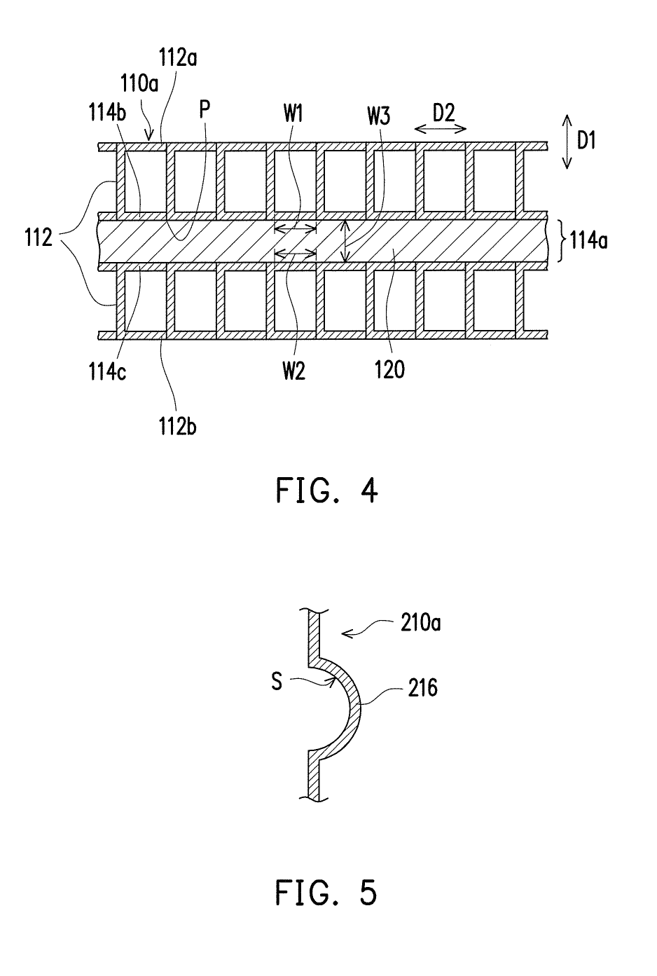

FIG. 2 is a schematic diagram showing a cooling fin set and a heat pipe in FIG. 1; FIG. 3 is a schematic diagram showing a cooling fin in FIG. 1; FIG. 4 is a section diagram showing the cooling fin set and the heat pipe in FIG. 2 along line I-I. Please refer to FIG. 2 to FIG. 4. The cooling fin set 110 includes a plurality of cooling fins 110a connected with each other. Each cooling fin 110a includes a fin body 112, a penetration portion 114, and a bending portion 116. The penetration portion 114 is formed on the fin body 112 and includes a slot 114a, a first bending wall 114b, and a second bending wall 114c. The first bending wall 114b and the second bending wall 114c are formed at the opposite sides of the slot 114a. The bending portion 116 is formed on the fin body 112 and adjacent to an end of the slot 114a. The heat pipe 120 passes through each penetration portion 114 via each slot 114a of the cooling fin set and contacts the first bending wall 114b and the second bending wall 114c of each penetration portion 114.

The cooling fin 110a further includes the bending portion 116 adjacent to the penetration portion 114. With the bending of the bending portion 116, the height of the cooling fin 110a in the first direction D1 is decreased and the distance between the first bending wall 114b and the second bending wall 114c (the width of the slot 114a in the first direction D1) is also decreased, therefore, a thinner heat pipe 120 can be configured between the first bending wall 114b and the second bending wall 114c of the heat dissipation module 100. The first direction D1 is perpendicular to the first bending wall 114b and the second bending wall 114c.

Moreover, as the height of the cooling fin 110a is decreased by forming the bending portion 116 instead of reducing the material of the penetration portion 114, therefore, the first bending wall 114b and the second bending wall 114c formed at the penetration portion 114 have enough width in the stamping process, and thus it can prevent solder paste from overflowing though a gap (as the position P shown in FIG. 4) formed between the first bending walls 114b (or second bending wall 114c) of the adjacent cooling fins 110a during the process of soldering the heat pipe 120.

Furthermore, the first bending walls 114b and the second bending walls 114c have enough width to have lager contacting area with the heat pipe 120, which can increase the heat dissipation efficiency between the cooling fin 110a and the heat pipe 120. By forming the bending portion 116 on the cooling fin 110a, the heat dissipation surface (the heat dissipation surface 116a shown in FIG. 3) is increased without increasing the height of the overall structure, so as to improve the heat dissipation ability of the heat dissipation module 100. The sum of the width W1 of the first bending wall 114b and the width W2 of the second bending wall 114c along the second direction D2 (the penetrating direction of the heat pipe 120) is larger than the distance between the first bending wall 114b and the second bending wall 114c (the width of the slot 114a along the first direction D1).

The bending degree of the bending portion 116 can be changed according to the thickness of the heat pipe 120 or other design need, which is not limited herein. For example, the thinner the heat pipe 120 is, the higher the bending degree of the bending portion 116 is needed, so as to make the distance between the two bending walls 114b and 114c small enough. The wider the bending degree of the bending portion 116 is, the longer the extending length of the bending portion 116 along the second direction D2 is.

In the embodiment, the fin body 112 includes a first baffle 112a and a second baffle 112b. The first baffle 112a and the second baffle 112b are connected to two opposite edges of the fin body 112. Airflow channel C1 (shown in FIG. 3) and airflow channel C2 are formed between the first bending wall 114b and the first baffle 112a, and between the second bending wall 114c and the second baffle 112b, respectively. The airflow generated by the fan 130 in FIG. 1 can sufficiently bring the heat of the cooling fin set 110 out by passing through the airflow passage C1 and the airflow passage C2. Since the first bending wall 114b and the second bending wall 114c have enough width, the airflow effectively passes the airflow passage C1 and the airflow passage C2 for advanced heat dissipation.

The cooling fin 110a includes a plurality of fastening slots 118a and a plurality of fastening portions 118b. The fastening slot 118a and the fastening portion 118b may be formed on the first baffle 112a and the second baffle 112b of the cooling fin 110a. The fastening portion 118b of the cooling fin 110a is fastened to the fastening slot 118a of the adjacent cooling fin 110a to make the cooling fins 110a connected to each other orderly. The cooling fin 110a further includes a protruding portion 118c, which is formed at the inner edge of the fastening slot 118a. When the fastening portion 118b is fastened to the corresponding fastening slot 118a, the fastening portion 118b interferes with the protruding portion 118c to make the connection of the cooling fins 110a more stable. In other embodiments, the cooling fins 110a can be connected with each other via other appropriate ways, which is not limited herein.

FIG. 5 is a partial section diagram showing a cooling fin in another embodiment. The section shape of the bending portion of the cooling fin is not limited herein, it may be an angle shape just like the bending portion 116 of the cooling fin 110a shown in FIG. 1 to FIG. 4, or it may be an arc-shape just like the bending portion 216 of the cooling fin 210a shown in FIG. 5. If the bending portion is the angle shape as shown in FIG. 1 to FIG. 4, the smaller the bending angle A (as shown in FIG. 3) is, the higher the bending degree is, and if the bending portion is the arc-shape as shown in FIG. 5, the larger the curvature of the cambered surface S is, the higher the bending degree is.

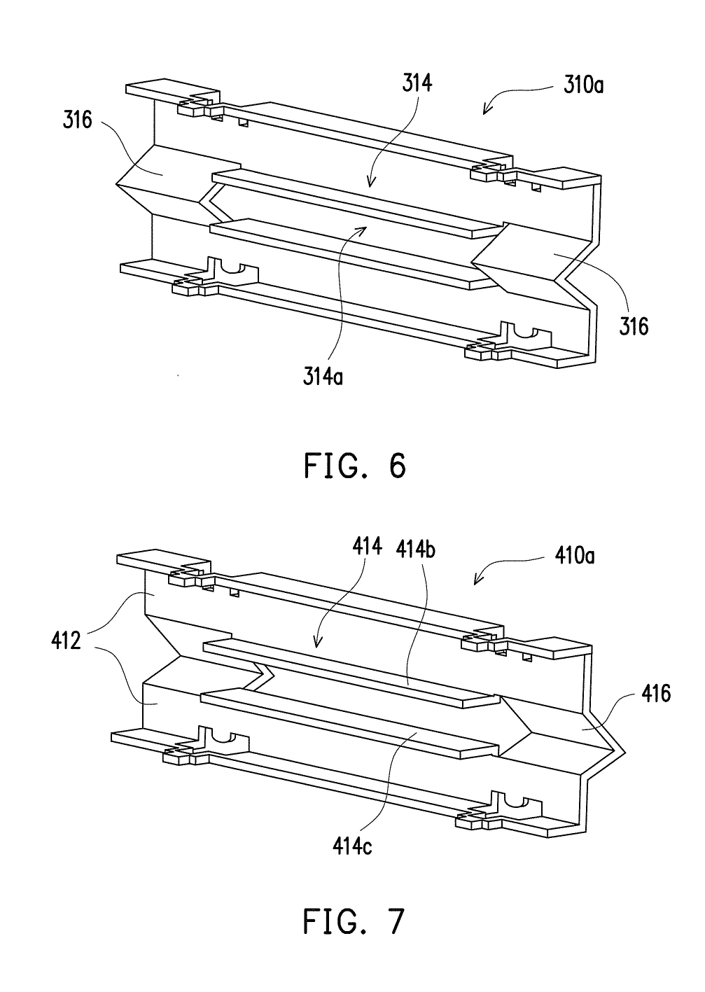

FIG. 6 is a schematic diagram showing a cooling fin in another embodiment. The number of the bending portion of the cooling fin is not limited herein, it may be one as the bending portion 116 of the cooling fin 110a shown in FIG. 1 to FIG. 4, or it also may be two as the bending portions 316 of the cooling fin 310a shown in FIG. 6. The two bending portions 316 are connected with the opposite sides of the slot 314a of the penetration portion 314.

FIG. 7 is a schematic diagram showing a cooling fin in further another embodiment. The extending direction of the bending wall and the bending portion of the cooling fin are not limited. For example, as the first bending wall 114b, the second bending wall 114c, and the bending portion 116 shown in FIG. 1 to FIG. 4, they extends from the same side of the fin body 112, or as the cooling fin 410a shown in FIG. 7, the first bending wall 414b and the second bending wall 414c of the penetration portion 414 are extended from a side of the fin body 412, and the bending portion 416 is extended from the other side of the fin body 412. Moreover, the number of the bending portion 416 can be two as shown in FIG. 7, and it also can be changed to one, which is not limited herein.

Although the present disclosure has been described in considerable detail with reference to certain preferred embodiments thereof, the disclosure is not for limiting the scope. Persons having ordinary skill in the art may make various modifications and changes without departing from the scope. Therefore, the scope of the appended claims should not be limited to the description of the preferred embodiments described above.

What is claimed is:

1. A cooling fin, comprising:
a fin body;
a penetration portion formed on the fin body and including a slot, a first bending wall, and a second bending wall, wherein the first bending wall and the second bending wall are formed at opposite sides of the slot; and
a first bending portion formed at the fin body and adjacent to one end of the slot.

2. The cooling fin according to claim 1, wherein the distance between the first bending wall and the second bending wall changes along with the bending degree of the first bending portion.

3. The cooling fin according to claim 1, wherein the fin body includes a first baffle and a second baffle, and the first baffle and the second baffle are disposed at the opposite sides of the fin body.

4. The cooling fin according to claim 1, further comprising a second bending portion disposed at the other end of the slot relative to the first bending portion.

5. The cooling fin according to claim 3, wherein an airflow channel is formed between the first bending wall and the first baffle.

6. The cooling fin according to claim 3, wherein an airflow channel is formed between the second bending wall and the second baffle.

7. A heat dissipation module, comprising:
a cooling fin set, including a plurality of cooling fins connected with each other, wherein each of the cooling fins including:
a fin body;
a penetration portion, formed on the fin body and including a slot, a first bending wall, and a second bending wall, wherein the first bending wall and the second bending wall are formed at opposite sides of the slot; and
a first bending portion, formed at the fin body and adjacent to one end of the slot; and
a heat pipe passing through each of the penetration portions via each of the slots and contacting the first bending wall and the second bending wall of the penetration portion.

8. The heat dissipation module according to claim 7, wherein the distance between the first bending wall and the second bending wall changes along with the bending degree of the first bending portion.

9. The heat dissipation module according to claim 7, wherein the fin body includes a first baffle and a second baffle, and the first baffle and the second baffle are disposed at the opposite sides of the fin body.

10. The heat dissipation module according to claim 7, further comprising a second bending portion disposed at an other side of the slot relative to the first bending portion.

11. The heat dissipation module according to claim 9, wherein an airflow channel is formed between the first bending wall and the first baffle.

12. The heat dissipation module according to claim 9, wherein an airflow channel is formed between the second bending wall and the second baffle.
